(19) United States
(12) Patent Application Publication
(10) Pub. No.: US 2009/0020824 A1
(43) Pub. Date: Jan. 22, 2009

(54) SEMICONDUCTOR DEVICE AND METHOD FOR PRODUCING THE SAME

(75) Inventor: Masaru KADOSHIMA, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/172,651

(22) Filed: Jul. 14, 2008

(30) Foreign Application Priority Data
Jul. 20, 2007 (JP) 2007-189356

(51) Int. Cl. H01L 29/00; H01L 21/3205

(52) U.S. Cl. 257/369; 438/592; 257/E29.001; 257/E21.294

(57) ABSTRACT

A complementary semiconductor device comprising an n-channel transistor and a p-channel transistor, including: the n-channel transistor including a gate insulating film and a first metal gate electrode formed on the gate insulating film and having a first compound layer including a first metal (M1) and silicon (Si); and the p-channel transistor including a gate insulating film and a second metal gate electrode formed on the gate insulating film and having a second compound layer including the first metal (M1), a second metal (M2), and silicon (Si), wherein the composition of the first compound layer is represented by a composition formula: M1Siₓ (1≦x), and the composition of the second compound layer is represented by a composition formula: M1M2Si_{y} (0<y≦0.5).

### CROSS-REFERENCE TO RELATED APPLICATION

The disclosure of Japanese Patent Application No. 2007-189356 filed on Jul. 20, 2007 including specification, drawings and claims is incorporated herein by reference in its entirety

### BACKGROUND OF THE INVENTION

1. Field of the Invention

The present invention relates to a semiconductor device and a method for producing the same and particularly to a complementary semiconductor device containing an MISFET having a metal gate electrode and a method for producing the same.

2. Description of the Related Art

In recent years, with respect to a C-MISFET (complementary metal insulator semiconductor FET (field effect transistor)), there is a problem that a gate insulating film of SION is made thin along with miniaturization and leakage current passing through the gate insulating film due to tunnel current.

In order to solve the problem, leakage current is prevented from occurring by using hafnium or hafnium silicate, which is a high-k material (a high dielectric constant material), for a material of the gate insulating film and making the thickness of the gate insulating film a given thickness. Further, in the case where the high-k material is used for a gate electrode, since Fermi-level pinning occurs in the interface with a silicon gate electrode, a metal gate electrode of nickel silicide, or the like is used in place of poly-silicon for the gate electrode material (e.g. 2006 Symposium on VLSI Technology Digest of Technical Papers, p. 116, and International Electron Devices Meeting 2004 Technical Digest, p. 83).

For example, in a C-MISFET using a high-k material for a gate insulating film, a nickel monosilicide phase (NiSi) for a metal gate electrode of a p-channel MISFET, a nickel-rich nickel silicide phase (Ni₂Si or the like) for an n-channel MISFET, the effective work function becomes 4.8 eV for the p-channel MISFET and 4.5 eV for the n-channel MISFET (e.g. U.S. Pat. No. 6,599,831).

### SUMMARY OF THE INVENTION

However, in view of further miniaturization, it is required to further lower the threshold voltage. That is, it is required to further increase the effective work function of the p-channel MISFET and to further lower the effective work function of the n-channel MISFET.

Further, in the step of forming a nickel silicide electrode, after a poly-silicon gate is formed on the n-channel and p-channel MISFETs, the poly-silicon gate of the p-channel MISFET is etched to a prescribed thickness by RIE and further silicidation of the poly-silicon gate is carried out. However, there occurs a variation in the thickness of the poly-silicon gate film formed by RIE and therefore, there is a problem of variations in the threshold voltage of the p-channel MISFET among devices.

Accordingly, an object of the present invention is to provide a semiconductor device containing a transistor having a low threshold voltage and free from a variation in threshold voltage among the transistors.

The present invention provides a complementary semiconductor device having an n-channel transistor and a p-channel transistor, in which the n-channel transistor includes a gate insulating film and a first metal gate electrode formed on the gate insulating film and having a first compound layer including a first metal (M1) and silicon (Si) and the p-channel transistor includes a gate insulating film and a second metal gate electrode formed on the gate insulating film and having a second compound layer including the first metal (M1), a second metal (M2), and silicon (Si); and the composition of the first compound layer is represented by a composition formula: M1Siₓ (1≦x) and the composition of the second compound layer is represented by a composition formula: M1M2Si_{y} (0<y≦0.5).

Further, the present invention also provides a method for producing a complementary semiconductor device having an n-channel transistor and a p-channel transistor, including the steps of preparing a semiconductor substrate; defining an n-channel transistor formation region and a p-channel transistor formation region in the semiconductor substrate and layering a gate insulating film, a first compound layer including a first metal (M1) and silicon (Si), and a dummy gate metal layer in the respective regions; selectively removing the dummy gate metal layer in the p-channel transistor formation region; forming a second metal (M2) layer to cover the semiconductor substrate; and forming a metal gate electrode of a second compound layer including the first metal (M1), the second metal (M2), and silicon (Si) by reacting the first compound layer and the second metal (M2) layer in the p-channel transistor formation region by heat treatment.

The present invention can provides a complementary semiconductor device containing transistors having a low threshold voltage and free from variations in threshold voltage among the transistors.

### BRIEF DESCRIPTION OF THE DRAWINGS

FIG. 1 shows a cross-sectional view of a semiconductor device according to a first embodiment of the present invention;

FIG. 1A shows a cross-sectional view of the production process of the semiconductor device according to the first embodiment of the present invention;

FIG. 1B shows a cross-sectional view of the production process of the semiconductor device according to the first embodiment of the present invention;

FIG. 1C shows a cross-sectional view of the production process of the semiconductor device according to the first embodiment of the present invention;

FIG. 1D shows a cross-sectional view of the production process of the semiconductor device according to the first embodiment of the present invention;

FIG. 1E shows a cross-sectional view of the production process of the semiconductor device according to the first embodiment of the present invention:

FIG. 2 shows a cross-sectional view of a semiconductor device according to a second embodiment of the present invention;

FIG. 2A shows a cross-sectional view of the production process of the semiconductor device according to the second embodiment of the present invention;

FIG. 2B shows a cross-sectional view of the production process of the semiconductor device according to the second embodiment of the present invention;

FIG. 2C shows a cross-sectional view of the production process of the semiconductor device according to the second embodiment of the present invention;

FIG. 3A shows the composition of the metal gate electrode before heat treatment; and

FIG. 3B shows the composition of the metal gate electrode after heat treatment.

### DETAILED DESCRIPTION OF THE PREFERRED EMBODIMENTS

### First Embodiment 1

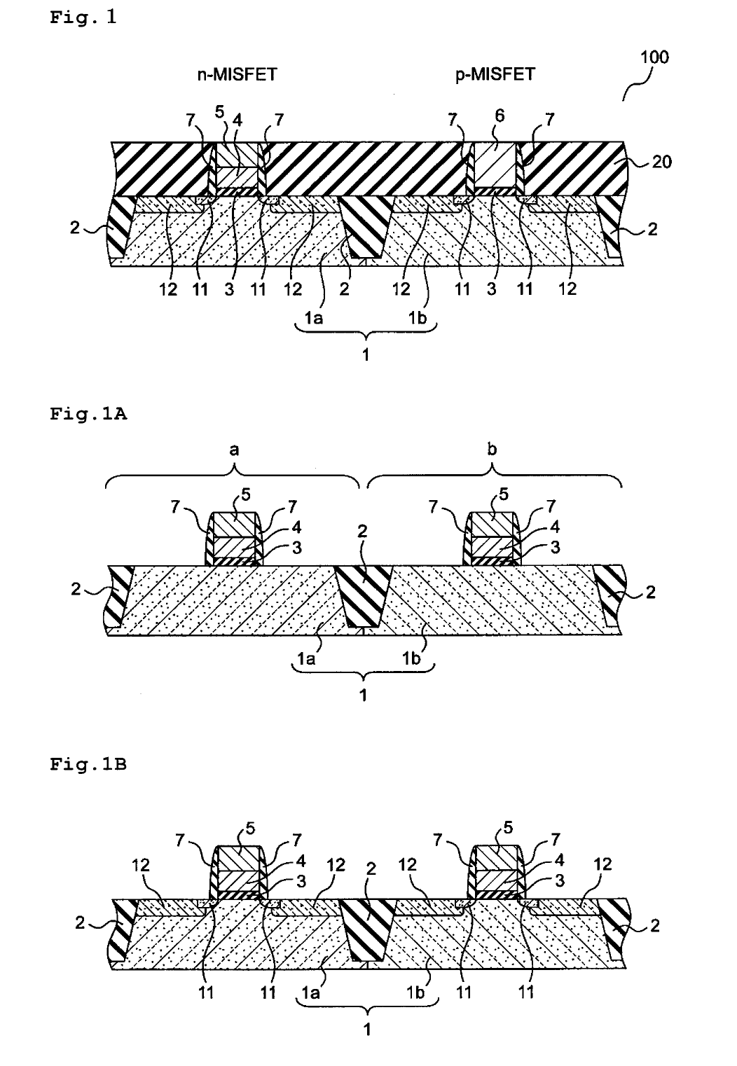

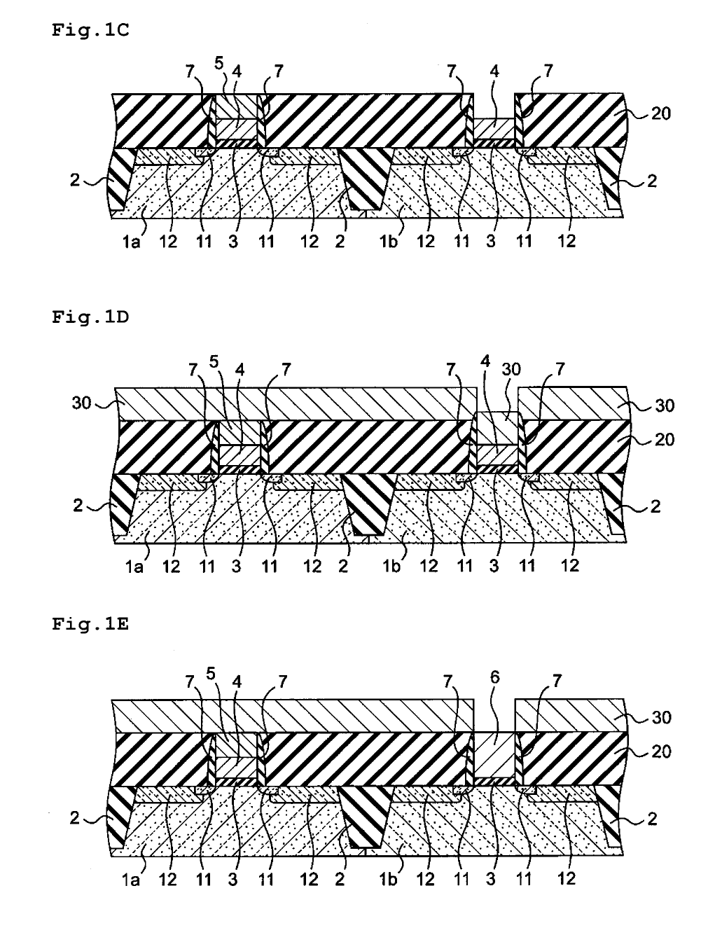

FIG. 1 shows a cross-sectional view of a semiconductor device according to a first embodiment, showing an entire semiconductor device 100. The semiconductor device 100 is a C-MISFET (complementary metal insulator semiconductor field effect transistor) containing an n-channel MISFET (n-MISFET) and a p-channel MISFET (p-MISFET).

The semiconductor device 100 has a semiconductor substrate 1 of, for example, silicon and a p-well region 1a and an n-well region 1b are formed in the semiconductor substrate 1. A device separation region 2 of, for example silicon oxide, is formed between the p-well region 1a and the n-well region 1b. A gate insulating film 3 of a high-k material is formed on the p-well region 1a and the n-well region 1b. The gate insulating film 3 is formed by using, for example, hafnium or hafnium silicate as well as silicon oxide, silicon oxynitride or the like.

On the p-well region 1a, a metal gate electrode including a tantalum silicide (TaSiₓ: x is 1 or higher and preferably about 2; a first compound including the first metal (M1) and silicon (Si)) layer 4 and a tungsten (W) layer 5 with the gate insulating film 3 interposed therebetween is formed. The side wall of the metal gate electrode is covered with a side wall 7 of, for example, silicon nitride.

On the other hand, on the n-well region 1b, a metal gate electrode including a nickel tantalum silicide (NiTaSi_{y}: y is higher than 0 and 0.5 or less; a second compound including the first metal (M1), a second metal (M2), and silicon (Si)) layer 6 with the gate insulating film 3 interposed therebetween is formed. The side wall of the metal gate electrode is covered with a side wall 7 of, for example, silicon nitride.

An n-type extension region 11 and an n-type source/drain region 12 are formed in the p-well region 1a so as to interpose the gate electrode. On the other hand, in the n-well region 3b, a p-type extension region 11 and a p-type source/drain region 12 are formed so as to interpose the gate electrode.

On the semiconductor substrate 1, an insulating layer 20 of, for example, silicon oxide is formed.

Next, with reference to FIGS. 1A to 1E, a method for producing the semiconductor device 100 of the first embodiment will be described. The production method involves the following steps 1 to 6.

Step 1: As shown in FIG. 1A, the semiconductor substrate 1, for example, of silicon is prepared. The p-well region 1a and the n-well region 1b are formed in the n-channel MISFET formation region a and the p-channel MISFET formation region b, respectively, by, for example, a diffusion method in the semiconductor substrate 1. Further, the device separation region 2, in which, for example, silicon oxide is embedded in a trench, is formed between the p-well region 1a and the n-well region 1b.

Successively, after the gate insulating film 3, the tantalum silicide layer 4, and the tungsten layer 5 are deposited by, for example, a CVD method, patterning in a gate electrode form is carried out using a resist mask. Further, a silicon nitride film is formed on the entire surface and the side wall 7 is formed by anisotropic etching.

Step 2: As shown in FIG. 1B, the extension region 11 and the source/drain region 12 are each formed by an ion implantation method.

Step 3: As shown in FIG. 1C, the interlayer insulating film 20 of, for example, silicon oxide is formed. Further, using a resist mask (not illustrated), the tungsten layer 5 in the p-channel MISFET b is selectively etched. For example, hydrogen peroxide water or the like may be used for the etching of the tungsten layer 5. In such an etching step, only the tungsten layer 5 is selectively etched and the tantalum silicide layer 4 as an under layer is not etched

Step 4: As shown in FIG. 1D, the nickel layer 30 is formed on the entire face by, for example, a sputtering method. The nickel layer 30 is formed on the interlayer insulating film 20 and the tantalum silicide layer 4.

Step 5: As shown in FIG. 1E, the nickel tantalum silicide (NiTaSi_{y}: y is 0.5 or less) layer 6 is formed by reacting the nickel layer 30 and the tantalum silicide layer 4 by heat treatment at, for example, 600° C.

Step 6: Finally, the nickel layer 30 on the interlayer insulating film 20 is removed by, for example, a CMP method or the like to complete the semiconductor device 100 as shown in FIG. 1.

In the semiconductor device 100 of the first embodiment, the thickness of the nickel tantalum silicide layer 6 can be accurately determined depending on the thicknesses of each of the tantalum silicide layer 4 and nickel layer 30. Since the thicknesses of the tantalum silicide layer 4 and nickel layer 30 can be accurately controlled by a CVD method or the like, the thickness of the nickel tantalum silicide layer 6 can be also accurately controlled.

As a result, it is made possible to almost completely eliminate the variation in the thickness of the nickel tantalum silicide layer 6 among devices and accordingly, a variation in threshold voltage can be eliminated.

Further, in the semiconductor device 100, the silicon composition x in the silicon composition (tantalum silicide (TaSiₓ)) layer 4 contained in the metal gate electrode of the n-channel MISFET is 1 or higher and preferably about 2 and on the other hand, the silicon composition y in the silicon composition (nickel tantalum silicide (NiTaSi_{y})) layer 6 contained in the metal gate electrode of the p-channel MISFET is higher than 0 and 0.5 or less. As a result, the work function of the n-channel/p-channel MISFET becomes 4.35 eV/4.80 eV and as compared with the work function, 4.50 eV/4.80 eV of a conventional n-channel/p-channel MISFET having a changed nickel silicide composition for the metal gate electrode, the work function of the gate electrode of the n-channel MISFET is lowered and thus the threshold voltage can be lowered.

### Second Embodiment

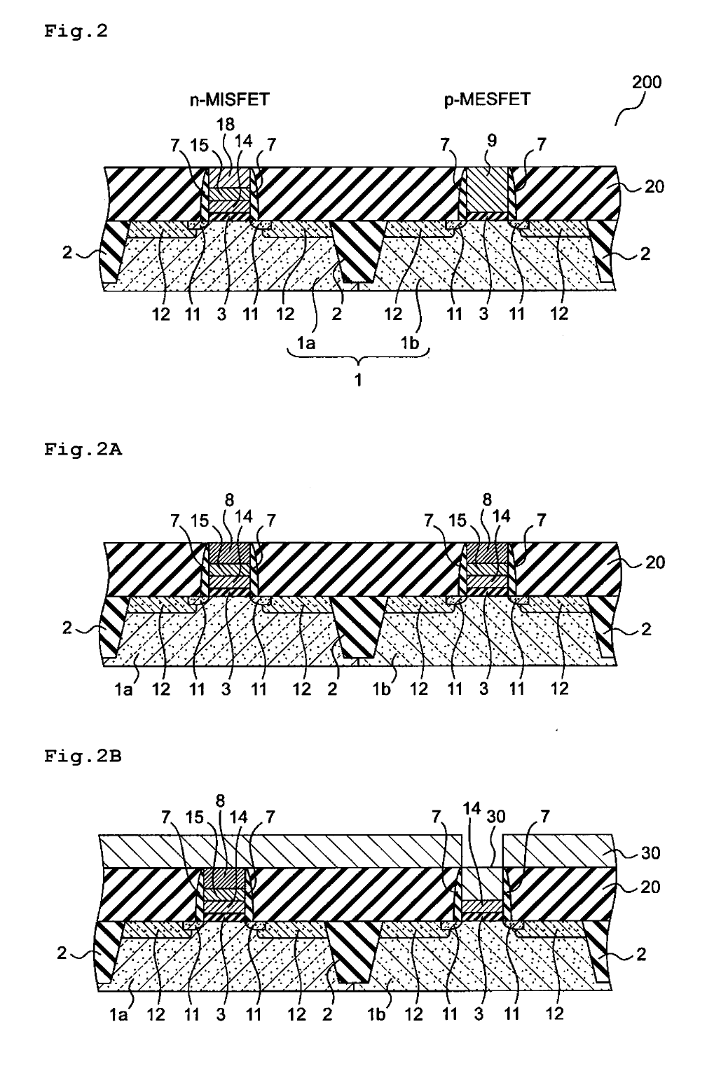

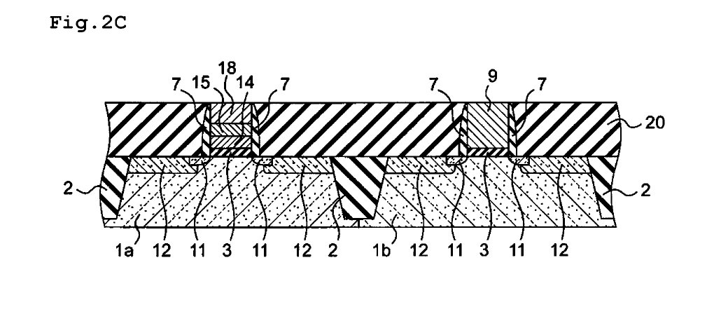

FIG. 2 shows a cross-sectional view of a semiconductor device according to a second embodiment, showing an entire semiconductor device 200. In FIG. 2, the same reference numerals and characters in FIG. 1 respectively show the same or equivalent parts.

The semiconductor device 200 has the same structure as that of the above-mentioned semiconductor device 100, except the structure of the metal gate electrode differs.

That is, in the semiconductor device 200, the metal gate electrode of the n-channel MISFET (n-MISFET) has a three layer structure including a tantalum silicide (TaSiₓ: x is 1 or higher and preferably about 2; a first compound including the first metal (M1) and silicon (Si)) layer 14, a titanium nitride (TiN) layer 15, and a nickel silicide (NiSi) layer 15.

On the other hand, the metal gate electrode of the p-channel MISFET (p-MISFET) includes a nickel tantalum silicide (NiTaSi_{y}: y is higher than 0 and 0.5 or less) layer 9.

The structure other than the above-mentioned structures is same as in the semiconductor device 100.

Next, the method for producing the semiconductor device 200 of the second embodiment will be described with reference to FIGS. 2A to 2C.

In the method for producing the semiconductor device 200, the structure shown in FIG. 2A is formed by carrying out the steps 1 and 2 (FIGS. 1A and 1B) of the first embodiment.

In the cross-sectional view of FIG. 2A, the metal gate electrode has the three-layer structure including the tantalum silicide (TaSiₓ: x is 1 or higher and preferably about 2; a first compound including the first metal (M1) and silicon (Si)) layer 14, the titanium nitride (TiN) layer 15, and a polycrystalline silicon layer 8. Further, an interlayer insulating film 20 of, for example, silicon oxide is formed on the semiconductor substrate 1.

Then, as shown in FIG. 2B, using a resist mask (not illustrated) or the like, the polycrystalline silicon layer 8 and titanium nitride layer 15 in the p-channel MISFET formation region are selectively removed. In practical, after the polycrystalline silicon layer 8 is removed by RIE, the titanium nitride layer 15 is selectively removed by wet etching using, for example, hydrogen peroxide water or the like. Accordingly, the tantalum silicide 14 as an under layer is not removed and only the polycrystalline silicon layer 8 and titanium nitride layer 15 as upper layers can be selectively removed.

Successively, the nickel layer 30 is formed on the entire surface by, for example, a CVD method.

Next, heat treatment at, for example, 600° C. is carried out. As a result, in the n-channel MISFET formation region, the polycrystalline silicon layer 8 and nickel layer 30 are reacted to form the nickel silicide (NiSi) layer 18. Herein, the titanium nitride layer 15 has a role of preventing the reaction of the tantalum silicide layer 14 and the polycrystalline silicon layer 8.

On the other had, in the p-channel MISFET, the tantalum silicide layer 14 and the nickel layer 30 are reacted to form the nickel tantalum silicide (NiTaSi_{y}: y is higher than 0 and 0.5 or less; a second compound including the first metal (M1), the second metal (M2), and silicon (Si)) layer 9.

Finally, the nickel layer 30 on the interlayer insulating film 20 is removed by, for example, a CMP method, a wet etching method, or like to complete the semiconductor device 200 as shown in FIG. 2.

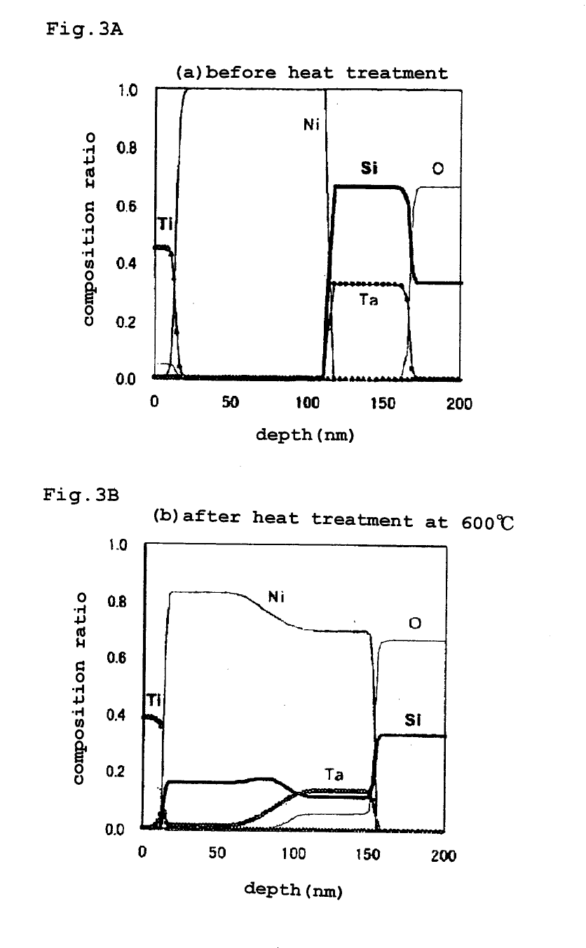

FIGS. 3A and 3B show the compositions of the gate electrode before and after the heat treatment of the metal gate electrode of the p-channel MISFET. The horizontal axis shows the distance in the depth direction from the upper end of the gate electrode and the vertical axis shows the composition ratio. The heat treatment temperature is set at 600° C.

In FIG. 3A, the portion to the depth of about 100 nm is a nickel layer and the layer under there is the tantalum silicide layer 14. The gate insulating film 3 is of silicon oxide.

As clear from FIG. 3B, after the heat treatment, in the upper region of the gate insulating film 3 (the region with a depth from about 100 nm to about 150 nm), it is understood that a NiTaSi layer with a low Si composition (0.5 or lower; in FIG. 3B, about 0.18) is formed.

Further, also in the semiconductor device 200 of the second embodiment, the thickness of the nickel tantalum silicide layer 9 can be accurately controlled. As a result, it is made possible to almost completely eliminate the variation in the thickness of the nickel tantalum silicide layer 6 among devices and accordingly, the variation in the threshold voltage can also be eliminated.

Further, in the semiconductor device 200, the silicon composition x in the silicon composition (tantalum silicide (TaSiₓ)) layer 4 contained in the metal gate electrode of the n-channel MISFET is 1 or higher and preferably about 2 and on the other hand, the silicon composition y in the silicon composition (nickel tantalum silicide (NiTaSi_{y})) layer 6 contained in the metal gate electrode of the p-channel MISFET is higher than 0 and 0.5 or less. As a result, the work function of the n-channel MISFET is lowered and thus the threshold voltage can be lowered.

In the first and second embodiments, the work function of the second metal (M2) is selected so as to be higher than that of the first metal (M1).

As the first metal (M1), in addition to Ta, rare earth metals such as Nb, V, Ti, Hf, Zr, La and the like may be used. Further, the second metal (M2), in addition to Ni, Pt, Ru, Ir, Pd, Co, and the like may be used.

Although the complementary semiconductor devices containing MISFETs is described, the present invention may be applied for complementary semiconductor devices containing MOSFETs.

What is claimed is:

1. A complementary semiconductor device comprising an n-channel transistor and a p-channel transistor, comprising:
the n-channel transistor including a gate insulating film and a first metal gate electrode formed on the gate insulating film and having a first compound layer including a first metal (M1) and silicon (Si); and
the p-channel transistor including a gate insulating film and a second metal gate electrode formed on the gate insulating film and having a second compound layer including the first metal (M1), a second metal (M2), and silicon (Si), wherein
the composition of the first compound layer is represented by a composition formula: M1Siₓ (1≦x), and
the composition of the second compound layer is represented by a composition formula: M1M2Si_{y} (0<y≦0.5).

2. The semiconductor device according to claim 1, wherein the first metal gate has a W layer on the first compound layer.

3. The semiconductor device according to claim 1, wherein the first metal gate has a TiN layer and a NiSi layer on the first compound layer.

4. The semiconductor device according to claim 1, wherein the work function of the second metal (M2) is higher than that of the first metal (M1).

5. The semiconductor device according to claim 1, wherein the first metal (M1) is a metal selected from the group consisting of Ta, Nb, V, Ti, Hf, Zr, and La.

6. The semiconductor device according to claim 1, wherein the second metal (M2) is a metal selected from the group consisting of Ni, Pt, Ru, Ir, Pd, and Co.

7. A method for producing a complementary semiconductor device having an n-channel transistor and a p-channel transistor, comprising the steps of:
preparing a semiconductor substrate;
defining an n-channel transistor formation region and a p-channel transistor formation region in the semiconductor substrate and forming a gate insulating film, a first compound layer including a first metal (M1) and silicon (Si), and a dummy gate metal layer in the respective regions;
selectively removing the dummy gate metal layer in the p-channel transistor formation region;
forming a second metal (M2) layer to cover the semiconductor substrate; and
forming a metal gate electrode of a second compound layer including the first metal (M1), the second metal (M2), and silicon (Si) by reacting the first compound layer and the second metal (M2) layer in the p-channel transistor formation region by heat treatment.

8. The semiconductor device production method according to claim 7, wherein the composition of the first compound layer is represented by a composition formula: M1Siₓ (1≦x) and
the composition of the second compound layer is represented by a composition formula: M1M2Si_{y} (0<y≦0.5).

9. The semiconductor device production method according to claim 7, wherein the work function of the second metal (M2) is higher than that of the first metal (M1).

10. The semiconductor device production method according to claim 7, wherein the first metal (M1) is a metal selected from the group consisting of Ta, Nb, V, Ti, Hf, Zr, and La.

11. The semiconductor device production method according to claim 7, wherein the second metal (M2) is a metal selected from the group consisting of Ni, Pt, Ru, Ir, Pd, and Co.
